(19) United States
(12) Patent Application Publication
(10) Pub. No.: US 2025/0318272 A1
(43) Pub. Date: Oct. 9, 2025

(54) SEMICONDUCTOR INTEGRATED CIRCUIT DEVICE

(71) Applicant: Socionext Inc., Kanagawa (JP)

(72) Inventor: Masachika ONO, Yokohama-shi (JP)

(21) Appl. No.: 19/242,640

(22) Filed: Jun. 18, 2025

Related U.S. Application Data
(63) Continuation of application No. PCT/JP2024/001518, filed on Jan. 19, 2024.

(30) Foreign Application Priority Data
Jan. 31, 2023 (JP) 2023-013404

(51) Int. Cl. H10D 89/10; H01L 23/528; H10D 84/83

(52) U.S. Cl. CPC H10D 89/10; H01L 23/5286; H10D 84/832

(57) ABSTRACT

In a semiconductor integrated circuit device, a plurality of cell rows each including standard cells arranged in the X direction are placed. The plurality of cell rows include a first cell row having a height H1 and a second cell row having a height H2 (H1<H2). The first cell row includes a logic cell and a cell having no logical function, and the second cell row includes a logic cell and a cell having no logical function. Nanosheets of the cells in the first cell row are smaller in width in the Y direction than nanosheets of the cells in the second cell row.

### CROSS-REFERENCE TO RELATED APPLICATIONS

This is a continuation of International Application No. PCT/JP2024/001518 filed on Jan. 19, 2024, which claims priority to Japanese Patent Application No. 2023-013404 filed on Jan. 31, 2023. The entire disclosures of these applications are incorporated by reference herein.

### BACKGROUND

The present disclosure relates to a semiconductor integrated circuit device.

As a method for forming a semiconductor integrated circuit on a semiconductor substrate, a standard cell method is known. The standard cell method is a method in which basic units (e.g., inverters, latches, flipflops, and full adders) having specific logical functions are prepared in advance as standard cells, and a plurality of such standard cells are placed on a semiconductor substrate and connected through interconnects, whereby an LSI chip is designed.

Also, as for a transistor, which is a basic constituent of an LSI, improvement in integration degree, reduction in operating voltage, and improvement in operating speed have been achieved by reducing (scaling) the gate length. In recent years, however, increase in off current due to excessive scaling and the resulting significant increase in power consumption have raised a problem. To solve this problem, three-dimensional transistors, of which the transistor structure has changed from the conventional planar structure to a three-dimensional structure, have been vigorously studied. A nanosheet FET is one example of such three-dimensional transistors.

WO 2020/170715 (Patent Document 1) discloses a structure of a terminal cell used for terminating a circuit block constituted by standard cells using complementary FETs (CFETs). The “terminal cell” is a cell used for terminating a circuit block without contributing to any logical function of the circuit block.

US Patent Application Publication No. 2022/0262786 (Patent Document 2) discloses a semiconductor integrated circuit device in which standard cell rows different in height are arranged alternately and some standard cells lie astride a plurality of standard cell rows.

US Patent Application Publication No. 2021/375853 (Patent Document 3) discloses, for further higher integration, a technique of providing interconnects on the back of a substrate right under transistors and connecting the sources/drains of the transistors to the interconnects.

However, Patent Document 2 has not disclosed a layout structure that includes standard cells having no logical function, such as terminal cells, in the semiconductor integrated circuit device having standard cell rows different in height.

An objective of the present disclosure is presenting a layout structure that includes standard cells having no logical function, in a semiconductor integrated circuit device having standard cell rows different in height.

### SUMMARY

According to the first mode of the disclosure, a semiconductor integrated circuit device includes: a first cell row including a plurality of standard cells arranged in a first direction; and a second cell row including a plurality of standard cells arranged in the first direction, wherein the first cell row includes a first standard cell including a first nanosheet extending in the first direction, the first standard cell having a logical function, and a second standard cell adjacent to the first standard cell, including a second nanosheet extending in the first direction, the second standard cell having no logical function, the first nanosheet and the second nanosheet are the same in width and position in a second direction perpendicular to the first direction, the second cell row includes a third standard cell including a third nanosheet extending in the first direction, the third standard cell having a logical function, and a fourth standard cell adjacent to the third standard cell, including a fourth nanosheet extending in the first direction, the fourth standard cell having no logical function, the third nanosheet and the fourth nanosheet are the same in width and position in the second direction, the first cell row includes a first power line formed on the back side of a transistor of the first standard cell, extending in the first direction, having overlaps with the first and second nanosheets in planar view, and supplying a first power supply voltage, the second cell row includes a second power line formed in a same interconnect layer as the first power line, extending in the first direction, having overlaps with the third and fourth nanosheets in planar view, and supplying the first power supply voltage, and the third and fourth nanosheets are greater in width in the second direction than the first and second nanosheets.

According to the above mode, the semiconductor integrated circuit device includes a first cell row and a second cell row. In the first cell row, a first nanosheet of a first standard cell having a logical function and a second nanosheet of a second standard cell having no logical function are the same in width and position in the second direction. In the second cell row, a third nanosheet of a third standard cell having a logical function and a fourth nanosheet of a fourth standard cell having no logical function are the same in width and position in the second direction. This improves the performance predictability of transistors of standard cells having logical functions, and also can reduce manufacturing variations and improve yield. Moreover, the third and fourth nanosheets are greater in width in the second direction than the first and second nanosheets. With this, since it is possible to form standard cells high in drive capability in the second cell row and form standard cells low in power consumption in the first cell row, the performance of the semiconductor integrated circuit device can be optimized.

According to the second mode of the disclosure, a semiconductor integrated circuit device includes: a plurality of cell rows each including a plurality of standard cells arranged in a first direction, wherein the plurality of cell rows include a first cell row including a first standard cell having a first nanosheet extending in the first direction, the first standard cell having a logical function, a second cell row adjacent to the first cell row in a second direction perpendicular to the first direction, having a height different from a height of the first cell row, and including a second standard cell having a second nanosheet extending in the first direction, and a third cell row located on an end of the plurality of cell rows in the second direction, adjoining the first cell row on the side opposite to the second cell row, and including a third standard cell having a third nanosheet extending in the first direction, the third standard cell having no logical function, the first cell row includes a first power line formed on the back side of a transistor of the first standard cell, extending in the first direction, having an overlap with the first nanosheet in planar view, and supplying a first power supply voltage, the second cell row includes a second power line formed in a same interconnect layer as the first power line, extending in the first direction, having an overlap with the second nanosheet in planar view, and supplying the first power supply voltage, and the third cell row includes a third power line formed in a same interconnect layer as the first and second power lines, extending in the first direction, having an overlap with the third nanosheet in planar view, and supplying the first power supply voltage, the first nanosheet and the second nanosheet are different in width in the second direction, and the third nanosheet and the second nanosheet are the same in width in the second direction.

According to the above mode, the semiconductor integrated circuit device includes: a first cell row; a second cell row adjacent to the first cell row in the second direction and different in height from the first cell row; and a third cell row located on an end of the plurality of cell rows in the second direction and adjacent to the first cell row on the side opposite to the second cell row. A first nanosheet of a first standard cell having a logical function in the first cell row is different in width in the second direction from a second nanosheet of a second standard cell in the second cell row. On the other hand, a third nanosheet of a third standard cell having no logical function in the third cell row is the same in width in the second direction as the second nanosheet. This improves the performance predictability of transistors of standard cells having logical functions, and also can reduce manufacturing variations and improve yield.

According to the present disclosure, in a semiconductor integrated circuit device having standard cell rows different in height, reduction in manufacturing variations, improvement in yield, and improvement in reliability can be achieved.

### BRIEF DESCRIPTION OF THE DRAWINGS

FIG. 1 is a plan view showing a layout example of a circuit block of a semiconductor integrated circuit device according to an embodiment.

FIG. 2 is an enlarged plan view of part W1 in FIG. 1, showing a layout structure of standard cells according to the first embodiment.

FIGS. 3A and 3B are cross-sectional views of the configuration of FIG. 2.

FIGS. 4A and 4B show another configuration example.

FIGS. 5A to 5C are plan views showing layout structures of terminal cells according to Alteration 1 of the first embodiment.

FIG. 6 is an enlarged plan view of part W2 in FIG. 1, showing a layout structure of standard cells according to the first embodiment.

FIGS. 7A-7B show examples of layout structures of double-height cells, where FIG. 7A shows a terminal cell and FIG. 7B shows a filler cell.

FIG. 8 is an enlarged plan view of part W3 in FIG. 1, showing a layout structure of standard cells according to the second embodiment.

FIG. 9 is an enlarged plan view of part W4 in FIG. 1, showing a layout structure of standard cells according to the second embodiment.

FIG. 10 is a plan view showing an alteration of the layout structure of FIG. 8.

FIG. 11 is a plan view showing an alteration of the layout structure of FIG. 9.

### DETAILED DESCRIPTION

Embodiments of the present disclosure will be described hereinafter with reference to the accompanying drawings. In the following embodiments, it is assumed that the semiconductor integrated circuit device includes a plurality of standard cells (hereinafter simply called cells as appropriate), and at least some of the standard cells include nanosheet field effect transistors (FETs). The nanosheet FET is a FET using a thin sheet (nanosheet) through which a current flows. Such a nanosheet is formed of silicon, for example. Note that, in the present disclosure, the transistors included in the standard cells are not limited to nanosheet FETs.

Note that, in the plan views and the cross-sectional views in the following embodiments, illustration of various insulating films may be omitted. As used herein, “VDD” and “VSS” refer to the power supply voltages or the power supplies themselves. Also, as used herein, an expression indicating that sizes such as widths are identical, like the “same wiring width,” is to be understood as including a range of manufacturing variations.

### (Configuration of Circuit Block)

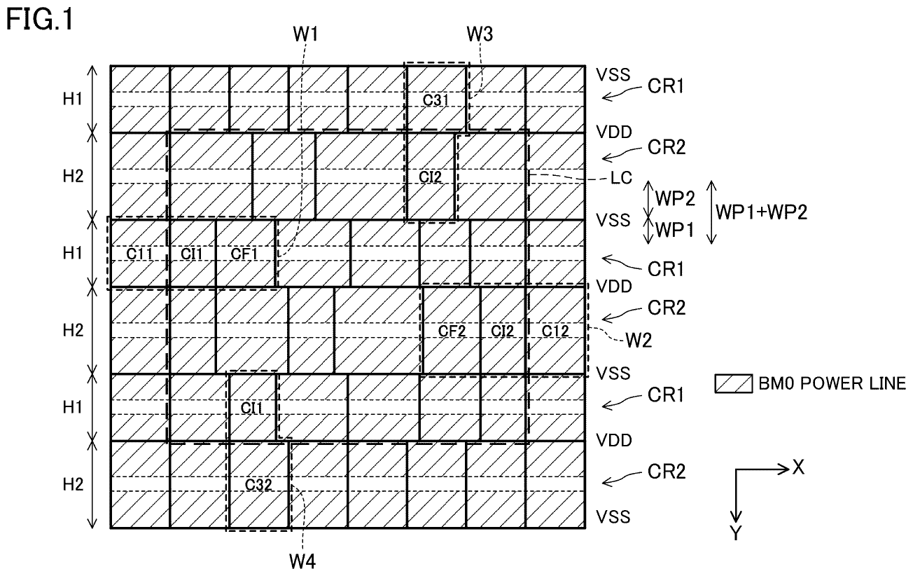

FIG. 1 is a plan view showing a layout example of a circuit block of a semiconductor integrated circuit device according to an embodiment. The block layout of FIG. 1 is configured by placing standard cells. In FIG. 1, only the cell frames of standard cells and power lines are illustrated, omitting illustration of the internal structures of the standard cells and interconnects between the standard cells.

Note that, in the plan views such as FIG. 1, the horizontal direction in the figure is hereinafter referred to as an X direction (corresponding to the first direction), the vertical direction in the figure as a Y direction (corresponding to the second direction), and the direction perpendicular to the substrate plane as a Z direction. Also, hereinafter, the same components are denoted by the same reference characters, and description of such components may not be repeated.

In the block layout of FIG. 1, a plurality of cells arranged in the X direction constitute cell rows CR1 and CR2. The height of the cell rows CR1 is H1, and the height of the cell rows CR2 is H2, where the height H2 is greater than the height H1 (H2>H1). A plurality of cell rows CR1 and CR2 (six rows in FIG. 1) are arranged in the Y direction. The cell rows CR1 and CR2 are placed alternately. Power lines are formed on both ends of the cells in the Y direction, through which power supply potentials VDD and VSS are supplied to the cells from outside. The power lines are formed in a backside metal 0 (BM0) layer that is an interconnect layer provided on the back of a semiconductor chip in which transistors are formed. The width of the power lines in the cell rows CR1 is WP1, and the width of the power lines in the cell rows CR2 is WP2, where the width WP2 is greater than the width WP1 (WP2>WP1). The cell rows CR1 and CR2 are placed in a vertically flipped position every other row so that the power lines between adjacent cell rows can be shared. The width of the power lines shared by the cell rows CR1 and CR2 is (WP1+WP2).

The plurality of cells include cells having logical functions, such as NAND gates and NOR gates (including inverter cells CI1 and CI2 having the logical function of inverters to be described later), and terminal cells and filler cells having no logical function.

The “terminal cells” as used herein refer to cells placed at terminals of the circuit block without contributing to any logical function of the circuit block. The “terminals of the circuit block” as used herein refer to both ends (in the X direction in this case) of the cell rows constituting the circuit block and the uppermost and lowermost rows (cell rows on both ends in the Y direction in this case) of the circuit block. That is, the “terminal cells” are placed at both ends of the cell rows in the X direction and in the cell rows on both ends in the Y direction, which are the terminals of the circuit block. By placing terminal cells, variations in the finished shape of the layout pattern of cells located inward with respect to the terminal cells in the circuit block can be reduced, whereby reduction in the manufacturing variations, improvement in the yield, and improvement in the reliability, of the semiconductor integrated circuit device can be achieved.

The “filler cells” as used herein refer to cells placed in spacings between cells having logical functions without contributing to any logical function of the circuit block.

In the layout of FIG. 1, a rectangular logical unit LC that includes logic cells having logical functions and implements a circuit function is placed in the center of the circuit block. A terminal cell unit is formed along the periphery of the circuit block so as to surround the logical unit LC. Filler cells are placed inside the logical unit LC.

In this embodiment, dummy gate interconnects are placed in the terminal cells. The “dummy gate interconnects” as used herein refer to a gate interconnect forming no transistor and a gate interconnect forming a transistor that does not contribute to the logical function of the circuit.

In FIG. 1, inverter cells CI1 and CI2 and filler cells CF1 and CF2 are placed in the logical unit LC, and terminal cells C11, C12, C31, and C32 are placed in the terminal cell unit. The inverter cell CI1, the filler cell CF1, and the terminal cells C11 and C31 are placed in the cell rows CR1 having the height H1. The inverter cell CI2, the filler cell CF2, and the terminal cells C12 and C32 are placed in the cell rows CR2 having the height H2.

In the terminal cell unit, terminal cells are placed in the following manner. In each cell row CR1, the terminal cell C11 is placed at the left end in the figure, and a terminal cell horizontally flipped from the terminal cell C11 is placed at the right end in the figure. In each cell row CR2, the terminal cell C12 is placed at the right end in the figure, and a terminal cell horizontally flipped from the terminal cell C12 is placed at the left end in the figure. In the uppermost cell row CR1 in the Y direction, the terminal cells C31 are placed in line in the X direction between the terminal cells at both ends in the figure. In the lowermost cell row CR2 in the Y direction, the terminal cells C32 are placed in line in the X direction between the terminal cells at both ends in the figure.

### First Embodiment

### (Layout of Part W1)

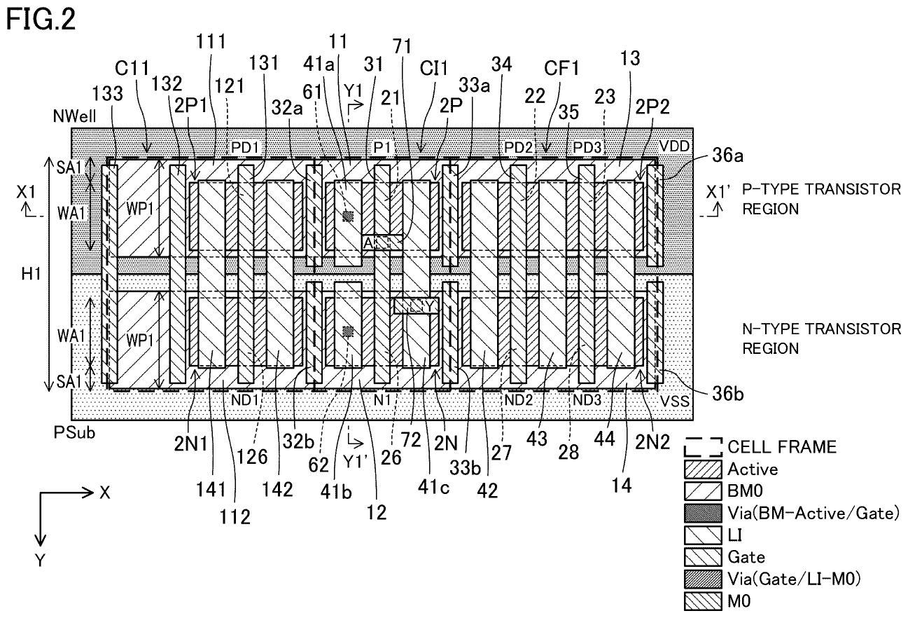

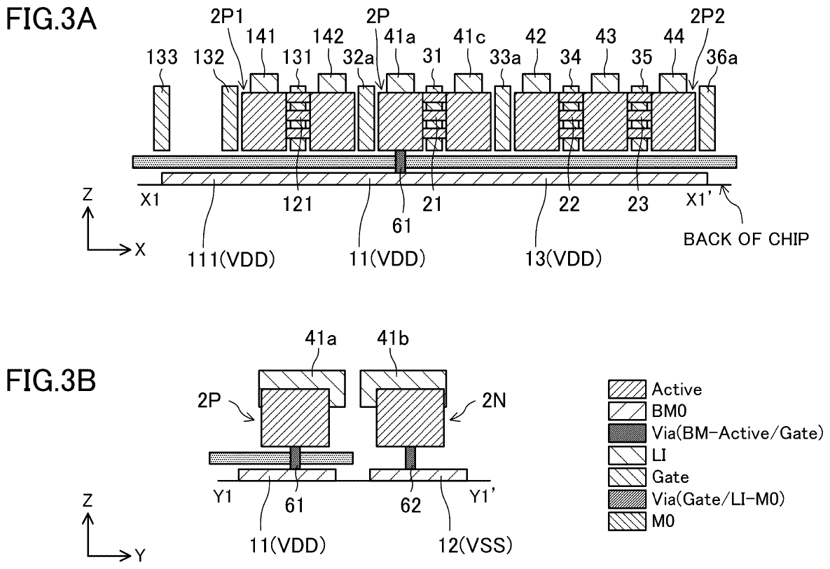

FIG. 2 is an enlarged plan view of part W1 in FIG. 1, showing a layout structure of standard cells in this embodiment. FIGS. 3A-3B are cross-sectional views of FIG. 2, where FIG. 3A shows a cross section taken along line X1-X1′ in FIG. 2, and FIG. 3B shows a cross section taken along line Y1-Y1′ in FIG. 2. Note that, in FIG. 2, the part W1 is vertically flipped from the one in FIG. 1.

As shown in FIG. 1, the part W1 is a part of the cell row CR1. In the part W1, the inverter cell CI1 is placed at the left end of the logical unit LC in the figure, and the terminal cell C11 is adjacently placed on the left side of the inverter cell CI1. Also, the filler cell CF1 is adjacently placed on the right side of the inverter cell CI1.

### (Configuration of Inverter Cell)

As shown in FIG. 2, in the inverter cell CI1, power lines 11 and 12 extending in the X direction are laid on the ends in the Y direction. The power lines 11 and 12 are formed in the BM0 layer that is an interconnect layer provided on the back of the semiconductor chip in which transistors are formed. The width of the power lines 11 and 12 is WP1. The power line 11 supplies the power supply voltage VDD, and the power line 12 supplies the power supply voltage VSS. The power lines 11 and 12 are shared with other cells in the cell row CR1 including the inverter cell CI1, forming power lines extending in the X direction. Also, the power lines 11 and 12 are shared between cell rows adjacent in the Y direction.

An active region 2P forming the channel, source, and drain of a p-type transistor is formed in a p-type transistor region on an n-type well (NWell). The active region 2P overlaps the power line 11 in planar view.

A p-type transistor P1 is formed in the p-type transistor region. The transistor P1 includes nanosheets 21 having a structure of three sheets lying one above another and extending in the X direction, as its channel. That is, the transistor P1 is a nanosheet FET. In the active region 2P, the portion that is to be the source of the transistor P1 is connected to the power line 11 through a via 61.

An active region 2N forming the channel, source, and drain of an n-type transistor is formed in an n-type transistor region on a p-type substrate (PSub). The active region 2N overlaps the power line 12 in planar view. Note that the n-type transistor region may be formed on a p-type well.

An n-type transistor N1 is formed in the n-type transistor region. The transistor N1 includes nanosheets 26 having a structure of three sheets lying one above another and extending in the X direction, as its channel. That is, the transistor N1 is a nanosheet FET. In the active region 2N, the portion that is to be the source of the transistor N1 is connected to the power line 12 through a via 62.

Note that, in the active regions, the portions that are to be the sources and the drains on the sides of the nanosheets are formed by epitaxial growth from the nanosheets, for example.

A gate interconnect 31 extends in the Y direction from the p-type transistor region over to the n-type transistor region. The gate interconnect 31 surrounds the peripheries of the nanosheets 21 of the transistor P1 and the nanosheets 26 of the transistor N1 in the Y and Z directions via gate insulating films (not shown). The gate interconnect 31 corresponds to the gates of the transistors P1 and N1.

In the p-type transistor region, dummy gate interconnects 32a and 33a are formed on the side portions of the cell frame in the X direction. In the n-type transistor region, dummy gate interconnects 32b and 33b are formed on the side portions of the cell frame in the X direction. The dummy gate interconnects 32a and 32b are shared with a cell placed on the left in the figure (the terminal cell C11 in FIG. 2), and the dummy gate interconnects 33a and 33b are shared with a cell placed on the right in the figure (the filler cell CF1 in FIG. 2).

The dummy gate interconnects 32a and 32b, the gate interconnect 31, and the dummy gate interconnects 33a and 33b are arranged at the same pitch in the X direction. Also, the gate interconnect 31 and the dummy gate interconnects 32a, 32b, 33a, and 33b have the same width in the X direction.

Local interconnects 41a, 41b, and 41c extending in the Y direction are formed in a local interconnect layer. Note that the local interconnects are represented as LI in the figures. The local interconnect 41a is connected to the portion that is to be the source of the transistor P1 in the active region 2P. The local interconnect 41b is connected to the portion that is to be the source of the transistor N1 in the active region 2N. The local interconnect 41c extends from the p-type transistor region over to the n-type transistor region, and is connected to the portion that is to be the drain of the transistor P1 in the active region 2P and the portion that is to be the drain of the transistor N1 in the active region 2N.

Metal interconnects 71 and 72 extending in the X direction are formed in an MO interconnect layer that is a metal interconnect layer located above the local interconnect layer. The metal interconnect 71 is connected to the gate interconnect 31 through a via. The metal interconnect 72 is connected to the local interconnect 41c through a via. The metal interconnect 71 corresponds to an input node A, and the metal interconnect 72 corresponds to an output node Y.

As described above, the inverter cell CI1, having the p-type transistor P1 and the n-type transistor N1, implements an inverter circuit having the input A and the output Y. That is, the inverter cell CI1 is a standard cell having a logical function.

### (Configuration of Terminal Cell)

As shown in FIG. 1, the terminal cell C11 is placed at the left end of the cell row CR1 in the X direction.

As shown in FIG. 2, in the terminal cell C11, power lines 111 and 112 extending in the X direction are laid on the ends in the Y direction. The power lines 111 and 112 are formed in the BM0 layer that is an interconnect layer provided on the back of the semiconductor chip in which transistors are formed. The power line 111 supplies the same power supply voltage VDD as the power line 11, and the power line 112 supplies the same power supply voltage VSS as the power line 12. The power line 111 is formed at the same position in the Y direction, and has the same width, as the power line 11. The power line 112 is formed at the same position in the Y direction, and has the same width, as the power line 12.

An active region 2P1 forming the channel, source, and drain of a p-type transistor is formed in the p-type transistor region on the n-type well (NWell). The active region 2P1 overlaps the power line 111 in planar view. A p-type transistor PD1 as a dummy transistor is formed in the p-type transistor region. The transistor PD1 includes nanosheets 121 having a structure of three sheets lying one above another and extending in the X direction, as its channel. The nanosheets 121 are the same in position and width in the Y direction as the nanosheets 21 in the inverter cell CI1.

An active region 2N1 forming the channel, source, and drain of an n-type transistor is formed in the n-type transistor region on the p-type substrate (PSub). The active region 2N1 overlaps the power line 112 in planar view. An n-type transistor ND1 as a dummy transistor is formed in the n-type transistor region. The transistor ND1 includes nanosheets 126 having a structure of three sheets lying one above another and extending in the X direction, as its channel. The nanosheets 126 are the same in position and width in the Y direction as the nanosheets 26 in the inverter cell CI1.

A dummy gate interconnect 131 extends in the Y direction from the p-type transistor region over to the n-type transistor region. The dummy gate interconnect 131 surrounds the peripheries of the nanosheets 121 of the transistor PD1 and the nanosheets 126 of the transistor ND1 in the Y and Z directions via gate insulating films (not shown).

On the left side of the dummy gate interconnect 131 in the figure, two dummy gate interconnects 132 and 133 extend in the Y direction from the p-type transistor region over to the n-type transistor region. The dummy gate interconnect 133 is placed on the left end of the terminal cell C11.

Local interconnects 141 and 142 extending in the Y direction are formed in the local interconnect layer. The local interconnect 141 extends from the p-type transistor region over to the n-type transistor region and is connected to the portion that is to be the drain of the transistor PD1 in the active region 2P1 and the portion that is to be the drain of the transistor ND1 in the active region 2N1. The local interconnect 142 extends from the p-type transistor region over to the n-type transistor region and is connected to the portion that is to be the source of the transistor PD1 in the active region 2P1 and the portion that is to be the source of the transistor ND1 in the active region 2N1.

In the terminal cell C11, none of the dummy gate interconnects 131, 132, and 133 and the local interconnects 141 and 142 are connected to other interconnects.

As described above, the terminal cell C11 does not have any operating transistor. That is, the terminal cell C11 is a standard cell having no logical function.

### (Configuration of Filler Cell)

As shown in FIG. 2, in the filler cell CF1, power lines 13 and 14 extend in the X direction on the ends in the Y direction. The power lines 13 and 14 are formed in the BM0 interconnect layer. The power line 13 supplies the same power supply voltage VDD as the power line 11, and the power line 14 supplies the same power supply voltage VSS as the power line 12. The power line 13 is formed at the same position in the Y direction, and has the same width, as the power line 11. The power line 14 is formed at the same position in the Y direction, and has the same width, as the power line 12.

An active region 2P2 forming the channel, source, and drain of a p-type transistor is formed in the p-type transistor region on the n-type well (NWell). The active region 2P2 overlaps the power line 13 in planar view. P-type transistors PD2 and PD3 as dummy transistors are formed in the p-type transistor region. The transistors PD2 and PD3 respectively include nanosheets 22 and 23 having a structure of three sheets lying one above another and extending in the X direction, as their channels. The nanosheets 22 and 23 are the same in position and width in the Y direction as the nanosheets 21 in the inverter cell CI1.

An active region 2N2 forming the channel, source, and drain of an n-type transistor is formed in the n-type transistor region on the p-type substrate (PSub). The active region 2N2 overlaps the power line 14 in planar view. N-type transistors ND2 and ND3 as dummy transistors are formed in the n-type transistor region. The transistors ND2 and ND3 respectively include nanosheets 27 and 28 having a structure of three sheets lying one above another and extending in the X direction, as their channels. The nanosheets 27 and 28 are the same in position and width in the Y direction as the nanosheets 26 in the inverter cell CI1.

Dummy gate interconnects 34 and 35 extend in the Y direction from the p-type transistor region over to the n-type transistor region. The dummy gate interconnect 34 surrounds the peripheries of the nanosheets 22 of the transistor PD2 and the nanosheets 27 of the transistor ND2 in the Y and Z directions via gate insulating films (not shown). The dummy gate interconnect 35 surrounds the peripheries of the nanosheets 23 of the transistor PD3 and the nanosheets 28 of the transistor ND3 in the Y and Z directions via gate insulating films (not shown).

On the cell frame on the right side of the dummy gate interconnect 35 in the figure, a dummy gate interconnect 36a is formed in the p-type transistor region, and a dummy gate interconnect 36b is formed in the n-type transistor region.

Local interconnects 42, 43, and 44 extend in the Y direction from the p-type transistor region over to the n-type transistor region. The local interconnect 42 is connected to the portion that is to be the drain of the transistor PD2 in the active region 2P2 and the portion that is to be the drain of the transistor ND2 in the active region 2N2. The local interconnect 43 is connected to the portion that is to be the source of the transistor PD2 and also the drain of the transistor PD3 in the active region 2P2 and the portion that is to be the source of the transistor ND2 and also the drain of the transistor ND3 in the active region 2N2. The local interconnect 44 is connected to the portion that is to be the source of the transistor PD3 in the active region 2P2 and the portion that is to be the source of the transistor ND3 in the active region 2N2.

In the filler cell CF1, none of the dummy gate interconnects 34, 35, 36a, and 36b and the local interconnects 42, 43, and 44 are connected to other interconnects.

As described above, the filler cell CF1 does not have any operating transistor. That is, the filler cell CF1 is a standard cell having no logical function.

As shown in FIGS. 2, 3A, and 3B, the active region 2P of the inverter cell CI1, the active region 2P1 of the terminal cell C11, and the active region 2P2 of the filler cell CF1 are the same in width in the Y direction (WA1) and position in the Y direction. That is, the nanosheets 21 of the inverter cell CI1, the nanosheets 121 of the terminal cell C11, and the nanosheets 22 and 23 of the filler cell CF1 are the same in width and position in the Y direction and also the same in the distance from the upper portion of the cell frame in the figure (SA1). Also, the active region 2N of the inverter cell CI1, the active region 2N1 of the terminal cell C11, and the active region 2N2 of the filler cell CF1 are the same in width in the Y direction (WA1) and position in the Y direction. That is, the nanosheets 26 of the inverter cell CI1, the nanosheets 126 of the terminal cell C11, and the nanosheets 27 and 28 of the filler cell CF1 are the same in width and position in the Y direction and also the same in the distance from the lower portion of the cell frame in the figure (SA1).

The dummy gate interconnects 131, 132, and 133 of the terminal cell C11 and the dummy gate interconnects 34 and 35 of the filler cell CF1 are formed at the same position in the Y direction, and have the same length, as the gate interconnect 31 of the inverter cell CI1. Also, the dummy gate interconnect 133, the dummy gate interconnect 132, the dummy gate interconnect 131, the dummy gate interconnects 32a and 32b, the gate interconnect 31, the dummy gate interconnects 33a and 33b, the dummy gate interconnect 34, the dummy gate interconnect 35, and the dummy gate interconnects 36a and 36b are arranged at the same pitch in the X direction, and the positions of both ends of these interconnects in the Y direction are the same.

The local interconnects 141 and 142 of the terminal cell C11 and the local interconnects 42, 43, and 44 of the filler cell CF1 are the same in the positions of both ends in the Y direction as the local interconnects 41a and 41b and the local interconnect 41c of the inverter cell CI1. Also, the local interconnect 141, the local interconnect 142, the local interconnects 41a and 41b, the local interconnect 41c, the local interconnect 42, the local interconnect 43, and the local interconnect 44 are arranged at the same pitch in the X direction.

Here, by providing the dummy gate interconnects and the local interconnects in the terminal cell, the gate interconnects including the dummy gate interconnects and the local interconnects are arranged regularly. It is therefore possible to reduce variations in the finished shape of the layout pattern of cells placed inward with respect to the terminal cells in the circuit block, whereby reduction in the manufacturing variations, improvement in the yield, and improvement in the reliability, of the semiconductor integrated circuit device can be achieved.

Also, the dummy gate interconnects 131 to 133 of the terminal cell C11 are formed with the same length in the Y direction as the gate interconnect 31 of the inverter cell CI1. This can reduce variations in the finished shape of the layout pattern, whereby the manufacturing variations of the semiconductor integrated circuit device can be reduced.

Moreover, the local interconnects 141 and 142 of the terminal cell C11 are placed so that the positions of both ends in the Y direction are the same as those of the local interconnects 41a and 41b and the local interconnect 41c of the inverter cell CI1. With this, since the distance from the logical unit LC to the nearest local interconnect can be made constant, the performance predictability of cells placed in the logical unit LC can be improved. Also, variations in the finished shape of the layout pattern can be reduced, whereby the manufacturing variations of the semiconductor integrated circuit device can be reduced.

While three dummy gate interconnects (131 to 133) and two local interconnects (141 and 142) are placed in the terminal cell C11 in the configuration of FIGS. 2, 3A, and 3B, the numbers of dummy gate interconnects and local interconnects placed in the terminal cell C11 are not limited to these. In the terminal cell C11, however, dummy gate interconnects and local interconnects of the numbers required to reduce variations in the finished dimensions of the ends of the logical unit are to be placed. The cell width (size in the X direction) of the terminal cell C11 may be changed depending on the numbers of dummy gate interconnects and local interconnects placed in the terminal cell C11.

While the dummy gate interconnects 131 to 133 of the terminal cell C11 are formed with the same length in the Y direction as the gate interconnect 31 of the inverter cell CI1 in the above description, the configuration is not limited to this, However, by forming these interconnects with the same length in the Y direction, the manufacturing variations of the circuit block can be more reduced.

Also, while the local interconnects 141 and 142 of the terminal cell C11 are placed so that the positions of both ends in the Y direction are the same as those of the local interconnects 41a and 41b and the local interconnect 41c of the inverter cell CI1 in the above description, the configuration is not limited to this, However, by placing these interconnects so that the positions of both ends in the Y direction are the same, the manufacturing variations of the circuit block can be more reduced.

In FIG. 1, a terminal cell flipped in the X direction from the terminal cell C11 is placed at the right end of the cell row CR1 in the figure.

While the power lines 11, 12, 13, 14, 111, and 112 are formed in the interconnect layer provided on the back of the semiconductor chip in the above description, the configuration is not limited to this. According to the present disclosure, it is only required for the power lines to be formed on the back side of the transistors. The “back side of the transistors” as used herein refers to the side, with respect to the transistors, opposite to the side on which the local interconnects, the metal interconnects, and the like connected to the transistors are stacked one upon another.

The power lines 11, 12, 13, 14, 111, and 112 may be formed in a plurality of interconnect layers.

### Other Configuration Example

The power lines on the back side of the transistors described above may also be formed using a semiconductor chip other than the semiconductor chip in which the transistors are formed.

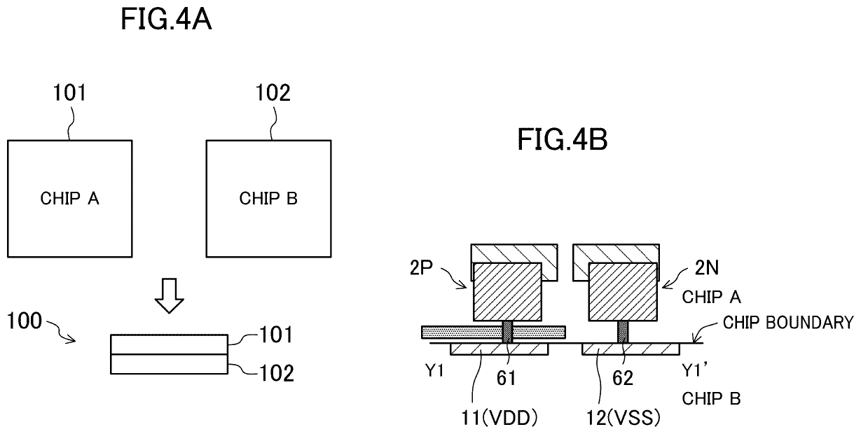

FIG. 4A shows another configuration example of the semiconductor integrated circuit device according to this embodiment. A semiconductor integrated circuit device 100 shown in FIG. 4A is constituted by a first semiconductor chip 101 (chip A) and a second semiconductor chip 102 (chip B) stacked one upon the other. In the chip A, the circuit block described above and the like are placed. In the chip B, power lines are formed in an interconnect layer provided on the surface. The chip B is bonded to the back of the chip A using bumps and the like.

FIG. 4B shows a cross section of this configuration example taken along line Y1-Y1′ in the inverter cell CI1 in FIG. 2. As shown in FIG. 4B, the power line 11 supplying VDD and the power line 12 supplying VSS are formed in the interconnect layer provided on the surface of the chip B. The power line 11 is connected to the active region 2P in the chip A through the via 61, and the power line 12 is connected to the active region 2N in the chip A through the via 62. The power lines 111 and 112 of the terminal cell C11 and the power lines 13 and 14 of the filler cell CF1 are also formed in the interconnect layer provided on the surface of the chip B.

Note that, in this configuration example, also, the power lines 11, 12, 13, 14, 111, and 112 may be formed in a plurality of interconnect layers.

### (Alterations of Terminal Cell)

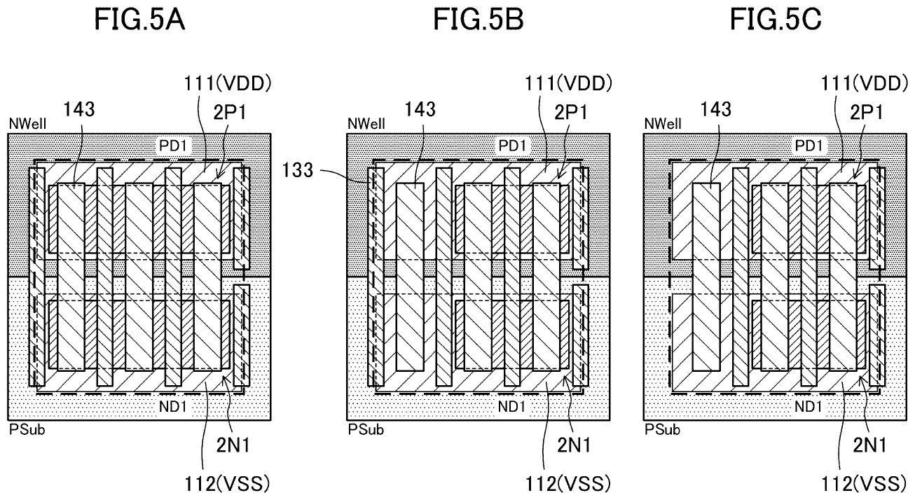

FIGS. 5A-5C are plan views showing layout configurations of alterations of the terminal cell. In the configuration of FIG. 5A, the active regions 2P1 and 2N1 further extend leftward in the figure, and a local interconnect 143 is added. In the configuration of FIG. 5B, there is no extension of the active regions 2P1 and 2N1, but the local interconnect 143 is added. In the configuration of FIG. 5C, the dummy gate interconnect 133 is deleted from the configuration of FIG. 5B.

Any of the terminal cells shown in FIGS. 5A to 5C may be placed instead of the terminal cell C11 in FIG. 2. Also, the active regions 2P1 and 2N1 may be omitted in the configurations of FIGS. 5A to 5C.

### (Layout of Part W2)

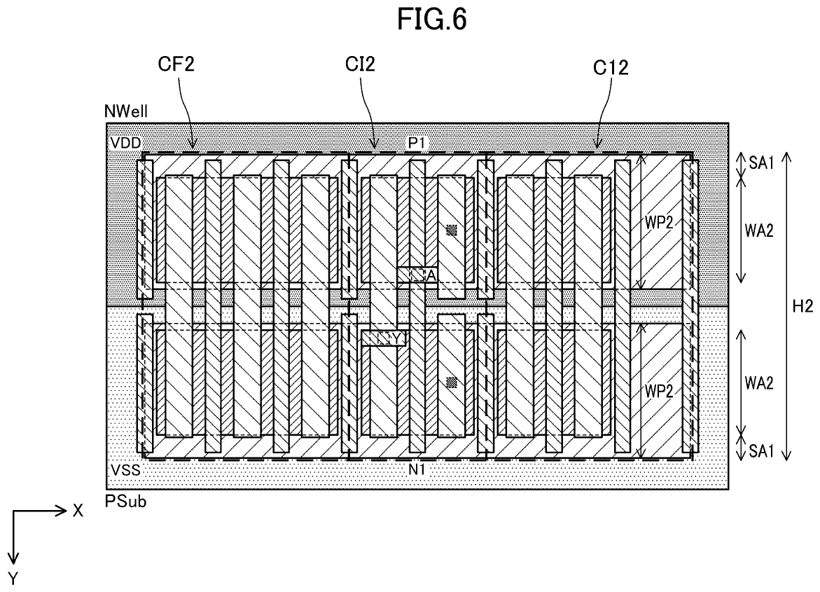

FIG. 6 is an enlarged plan view of part W2 in FIG. 1, showing a layout structure of standard cells in this embodiment. As shown in FIG. 1, the part W2 is a part of the cell row CR2. In the part W2, the inverter cell CI2 is placed at the right end of the logical unit LC in the figure, and the terminal cell C12 is adjacently placed on the right side of the inverter cell CI2. The filler cell CF2 is adjacently placed on the left side of the inverter cell CI2.

The layout of FIG. 6 is roughly the same as one horizontally flipped from the layout of FIG. 2. However, since the cell height H2 is higher than the cell height H1 in FIG. 2, the sizes of the components are different from those in the layout of FIG. 2. Also, the width of the power lines is WP2, which is greater than the width WP1 of the power lines shown in FIG. 2 (WP2>WP1). Since details of the layout can be easily known by analogy from the details described above, description thereof is omitted here.

As shown in FIG. 6, on the n-type well, the active regions of the inverter cell CI2, the terminal cell C12, and the filler cell CF2 are the same in width in the Y direction (WA2) and position in the Y direction. That is, the nanosheets in the p-type transistor region in the part W2 are the same in width and position in the Y direction. The width WA2 is greater than the width WA1 in the layout of FIG. 2. Also, the nanosheets in the p-type transistor region in the part W2 are the same in the distance from the upper portion of the cell frame in the figure (SA1), and this distance is the same as the distance SA1 in the part W1 shown in FIG. 2.

Also, on the p-type substrate, the active regions of the inverter cell CI2, the terminal cell C12, and the filler cell CF2 are the same in width in the Y direction (WA2) and position in the Y direction. That is, the nanosheets in the n-type transistor region in the part W2 are the same in width and position in the Y direction. Also, the nanosheets in the n-type transistor region in the part W2 are the same in the distance from the lower portion of the cell frame in the figure (SA1), and this distance is the same as the distance SA1 in the part W1 shown in FIG. 2.

Having the layouts of the parts W1 and W2 described above, the following effects are obtained.

The width WA1 of the nanosheets in the Y direction in the part W1 of the cell row CR1 is smaller than the width WA2 of the nanosheets in the Y direction in the part W2 of the cell row CR2 (WA1<WA2). It is therefore possible to form standard cells high in drive capability in the cell row CR2 having the cell height H2 and form standard cells low in power consumption in the cell row CR1 having the cell height H1. In this way, the performance of the semiconductor integrated circuit device can be optimized.

In the part W1, the active regions and nanosheets of the terminal cell C11 and the filler cell CF1 are made the same in width and position in the Y direction as the active regions and nanosheets of the inverter cell CI1. Also, in the part W2, the active regions and nanosheets of the terminal cell C12 and the filler cell CF2 are made the same in width and position in the Y direction as the active regions and nanosheets of the inverter cell CI2. With this, the widths and positions in the Y direction of active regions adjacent to the active regions of the inverter cell can be made invariably constant. This improves the performance predictability of transistors constituting the inverter, and also can reduce the manufacturing variations, and improve the yield, of the semiconductor integrated circuit device.

Note that, while the inverter cell is used as an example of the logic cell in the above-described layout, a logic cell other than the inverter, such as a NAND cell, a NOR cell, and an FF cell, may be placed. In this case, also, similar effects can be obtained by arranging the logic cell and its adjacent terminal cell and filler cell so that their active regions and nanosheets are the same in width and position in the Y direction.

### (Double-Height Cell)

The terminal cell and the filler cell each may be formed as a double-height cell extending from the cell row CR1 having the height H1 over to the cell row CR2 having the height H2.

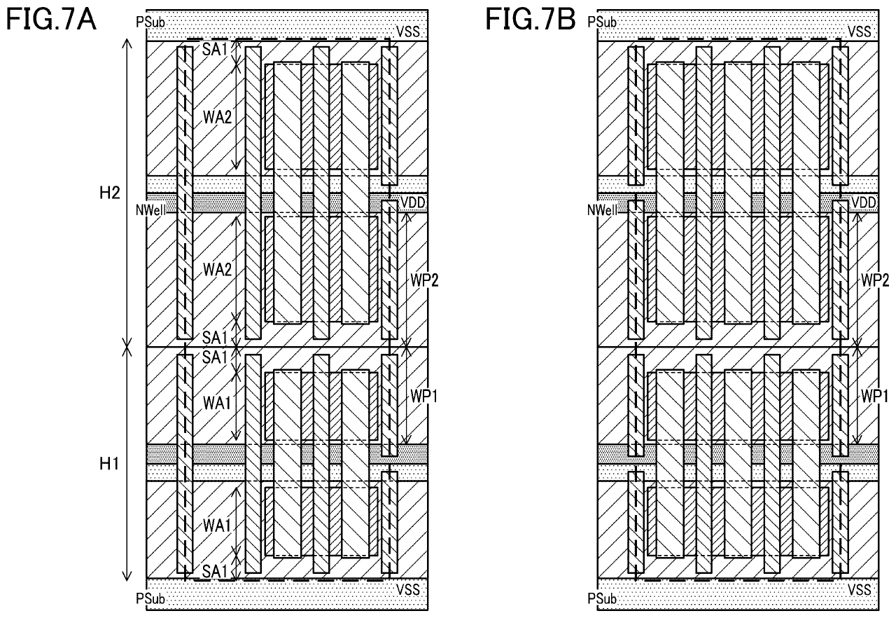

FIGS. 7A-7B show examples of layout structures of double-height cells, where FIG. 7A shows a terminal cell and FIG. 7B shows a filler cell. The configuration of the terminal cell of FIG. 7A is equivalent to a configuration obtained by coupling a vertically and horizontally flipped one of the terminal cell C12 shown in FIG. 6 onto the top of the terminal cell C11 shown in FIG. 2 in the figure. The configuration of the filler cell of FIG. 7B is equivalent to a configuration obtained by coupling a vertically flipped one of the filler cell CF2 shown in FIG. 6 onto the top of the filler cell CF1 shown in FIG. 2 in the figure. Since details of the configurations can be easily understood from the details described above, description thereof is omitted here.

In the design of a semiconductor integrated circuit device, by preparing and using double-height cells as those shown in FIGS. 7A-7B, an effect of reducing the design data amount can be obtained.

### Second Embodiment

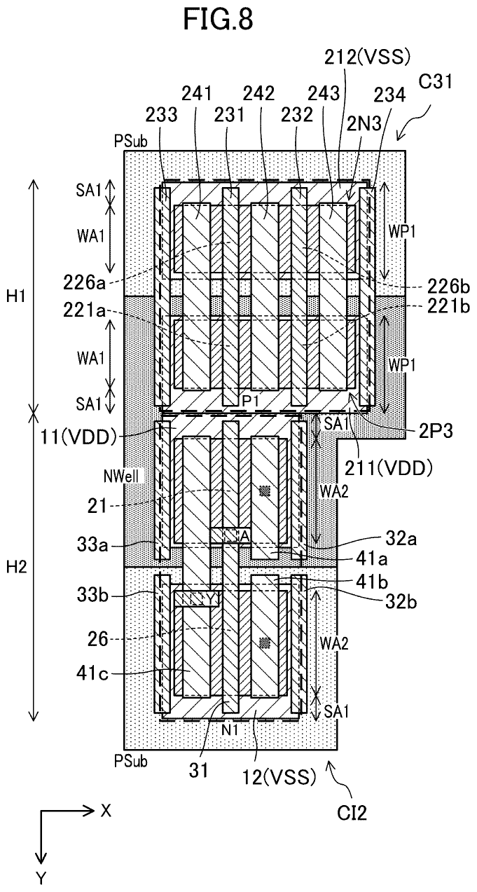

FIG. 8 is an enlarged plan view of part W3 in FIG. 1, showing a layout structure of standard cells according to the second embodiment. As shown in FIG. 1, the terminal cell C31 is placed in the uppermost cell row CR1 of the circuit block in the Y direction. Also, the terminal cell C31 is placed adjacently on the upper side of the inverter cell CI2 in the cell row CR2 that is located on the upper end of the logical unit LC in the figure.

As shown in FIG. 8, in the terminal cell C31, power lines 211 and 212 extending in the X direction are laid on the ends in the Y direction. The power lines 211 and 212 are formed in the BM0 layer that is the interconnect layer provided on the back of the semiconductor chip in which transistors are formed. The width of the power lines 211 and 212 is WP1. The power line 211 is formed integrally with the power line 11 of the inverter cell CI2 and supplies the same power supply voltage VDD as the power line 11. The power line 212 supplies the same power supply voltage VSS as the power line 12.

In the terminal cell C31, an active region 2P3 forming the channel, source, and drain of a p-type transistor is formed in the p-type transistor region on the n-type well (NWell). The active region 2P3 overlaps the power line 211 in planar view. The active region 2P3 includes nanosheets 221a and 221b constituting dummy transistors. The nanosheets 221a and 221b each have a structure of three sheets lying one above another and extend in the X direction.

An active region 2N3 forming the channel, source, and drain of an n-type transistor is formed in the n-type transistor region on the p-type substrate (PSub). The active region 2N3 overlaps the power line 212 in planar view. The active region 2N3 includes nanosheets 226a and 226b constituting dummy transistors. The nanosheets 226a and 226b each have a structure of three sheets lying one above another and extend in the X direction.

Dummy gate interconnects 231 and 232 extend in the Y direction from the p-type transistor region over to the n-type transistor region. The dummy gate interconnect 231 surrounds the peripheries of the nanosheets 221a in the active region 2P3 and the nanosheets 226a in the active region 2N3 in the Y and Z directions via gate insulating films (not shown). The dummy gate interconnect 232 surrounds the peripheries of the nanosheets 221b in the active region 2P3 and the nanosheets 226b in the active region 2N3 in the Y and Z directions via gate insulating films (not shown).

On the left side of the dummy gate interconnect 231 in the figure, a dummy gate interconnect 233 extends in the Y direction from the p-type transistor region over to the n-type transistor region. The dummy gate interconnect 233 is formed on the left end of the terminal cell C31 in the figure. On the right side of the dummy gate interconnect 232 in the figure, a dummy gate interconnect 234 extends in the Y direction from the p-type transistor region over to the n-type transistor region. The dummy gate interconnect 234 is formed on the right end of the terminal cell C31 in the figure.

Local interconnects 241, 242, and 243 extending in the Y direction are formed in the local interconnect layer. The local interconnect 241, extending from the p-type transistor region over to the n-type transistor region, is connected to the portion between the dummy gate interconnects 231 and 233 in the active region 2P3 and the portion between the dummy gate interconnects 231 and 233 in the active region 2N3. The local interconnect 242, extending from the p-type transistor region over to the n-type transistor region, is connected to the portion between the dummy gate interconnects 231 and 232 in the active region 2P3 and the portion between the dummy gate interconnects 231 and 232 in the active region 2N3. The local interconnect 243, extending from the p-type transistor region over to the n-type transistor region, is connected to the portion between the dummy gate interconnects 232 and 234 in the active region 2P3 and the portion between the dummy gate interconnects 232 and 234 in the active region 2N3.

In the terminal cell C31, none of the dummy gate interconnects 231, 232, 233, and 234 and the local interconnects 241, 242 and 243 are connected to other interconnects.

As described above, the terminal cell C31 does not have any operating transistor. That is, the terminal cell C31 is a standard cell having no logical function.

As shown in FIG. 8, the width of the active regions 2P3 and 2N3 and the nanosheets 221a, 221b, 226a, and 226b in the Y direction is WA1, which is the same as the width of active regions and nanosheets in a cell in the cell row CR1 located adjacently on the lower side of the inverter cell CI2 in the figure. Also, the nanosheets 221a and 226a in the terminal cell C31 are formed at the same position in the X direction as the nanosheets 21 and 26 in the inverter cell CI2.

The dummy gate interconnects 231, 232, 233, and 234 in the terminal cell C31 are arranged at the same pitch in the X direction, and the positions of both ends of these interconnects in the Y direction are the same. Also, the dummy gate interconnect 231 in the terminal cell C31 is placed at the same position in the X direction as the gate interconnect 31 in the inverter cell CI2. The dummy gate interconnect 232 in the terminal cell C31 is placed at the same position in the X direction as the dummy gate interconnects 32a and 32b in the inverter cell CI2. The dummy gate interconnect 233 in the terminal cell C31 is placed at the same position in the X direction as the dummy gate interconnects 33a and 33b in the inverter cell CI2.

The local interconnects 241, 242, and 243 in the terminal cell C31 are arranged at the same pitch in the X direction, and the positions of both ends of these interconnects in the Y direction are the same. Also, the local interconnect 241 in the terminal cell C31 is placed at the same position in the X direction as the local interconnect 41c in the inverter cell CI2. The local interconnect 242 in the terminal cell C31 is placed at the same position in the X direction as the local interconnects 41a and 41b in the inverter cell CI2.

According to the configuration of FIG. 8, the terminal cell C31 having the height H1 is placed adjacently on the upper side of the inverter cell CI2 that is located in the uppermost row of the logical unit LC in the figure. Therefore, as for the p-type transistor P1 of the inverter cell CI2, the position and width of nanosheets adjacent in the Y direction (the nanosheets 221a of the terminal cell C31) are the same as those when a cell having the height H1 other than a terminal cell (e.g., the inverter cell CI1 or the filler cell CF1) is placed adjacent to the inverter cell CI2 in the Y direction. This improves the performance predictability of transistors constituting the inverter cell, and also reduces the manufacturing variations, and improves the yield, of the semiconductor integrated circuit device.

Also, the distance of the nanosheets 221a and 221b of the terminal cell C31 from the boundary between the inverter cell CI2 and the terminal cell C31 is the same as that of the nanosheets 21 of the inverter cell CI2. It is therefore possible to reduce variations in the finished shape of the layout pattern of cells placed inward with respect to the terminal cells in the circuit block, whereby reduction in the manufacturing variations, improvement in the yield, and improvement in the reliability, of the semiconductor integrated circuit device can be achieved.

Also, the terminal cell C31 includes the dummy transistors, the dummy gate interconnects, and the local interconnects. In the terminal cell C31, the nanosheets are formed at the same positions in the X direction as the nanosheets of the inverter cell CI2, the dummy gate interconnects are placed at the same positions in the X direction as the gate interconnects of the inverter cell CI2, and the local interconnects are placed at the same positions in the X direction as the local interconnects of the inverter cell CI2. With this, the transistors including the dummy transistors, the gate interconnects including the dummy gate interconnects, and the local interconnects are arranged regularly. It is therefore possible to reduce variations in the finished shape of the layout pattern of cells placed inward with respect to the terminal cells in the circuit block, whereby reduction in the manufacturing variations, improvement in the yield, and improvement in the reliability, of the semiconductor integrated circuit device can be achieved.

Note that the cell width of the terminal cell C31 is not limited to that shown in FIG. 8.

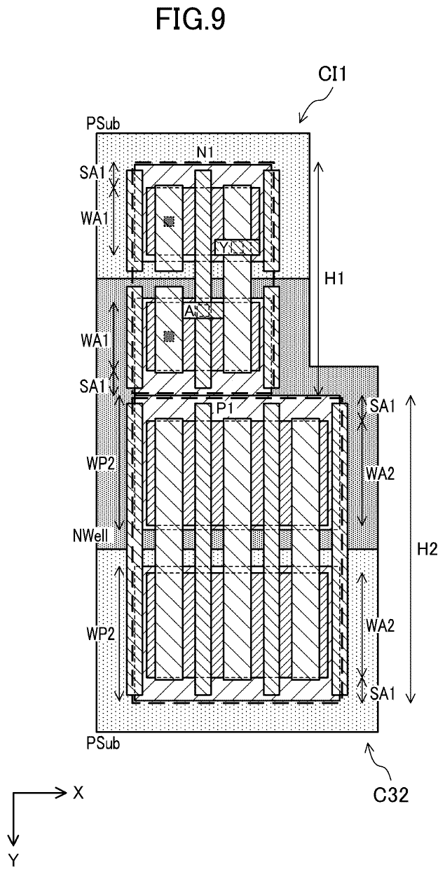

FIG. 9 is an enlarged plan view of part W4 in FIG. 1, showing a layout structure of standard cells according to this embodiment. As shown in FIG. 1, the terminal cell C32 is placed in the lowermost cell row CR2 of the circuit block in the Y direction. Also, the terminal cell C32 is placed adjacently on the lower side of the inverter cell CI1 in the cell row CR1 located on the lower end of the logical unit LC in the figure.

The configuration of FIG. 9 is equivalent to a configuration obtained by vertically flipping the configuration of FIG. 8 and exchanging the heights of the terminal cell and the inverter cell. Since details of the layout structure can be easily understood from the details described above, description thereof is omitted here.

According to the configuration of FIG. 9, the terminal cell C32 having the height H2 is placed adjacently on the lower side of the inverter cell CI1 that is located in the lowermost row of the logical unit LC in the figure. Therefore, as for the p-type transistor P1 of the inverter cell CI1, the position and width of nanosheets adjacent in the Y direction (nanosheets of the terminal cell C32) are the same as those when a cell having the height H2 other than a terminal cell (e.g., the inverter cell CI2 or the filler cell CF2) is placed adjacent to the inverter cell CI1 in the Y direction. This improves the performance predictability of transistors constituting the inverter cell, and also reduces the manufacturing variations, and improves the yield, of the semiconductor integrated circuit device.

Also, in the configuration of FIG. 9, which has characteristics similar to those of the configuration of FIG. 8, it is possible to reduce variations in the finished shape of the layout pattern of cells placed inward with respect to the terminal cells in the circuit block, whereby reduction in the manufacturing variations, improvement in the yield, and improvement in the reliability, of the semiconductor integrated circuit device can be achieved.

Note that the cell width of the terminal cell C32 is not limited to that shown in FIG. 9.

### (Alterations)

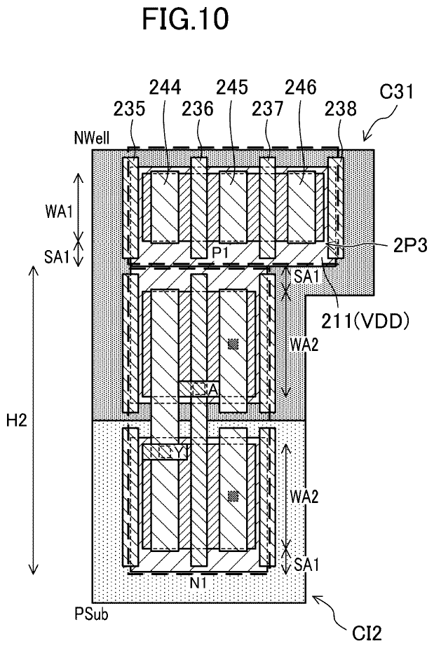

FIG. 10 is a plan view showing a layout structure of a terminal cell according to an alteration of this embodiment. In the configuration of FIG. 10, the upper VSS-side part of the terminal cell C31 in FIG. 8 is omitted. That is, the power line 212 and the active region 2N3 are omitted, the dummy gate interconnects 231 to 234 are replaced with short dummy gate interconnects 235 to 238, and the local interconnects 241 to 243 are replaced with short local interconnects 244 to 246. The terminal cell C31 in FIG. 10 is smaller in size in the Y direction than cells having the height H1 in the cell rows CR1 inside the logical unit LC. The terminal cell C31 in FIG. 10 has only a p-type transistor, having no n-type transistor.

In the configuration of FIG. 10, also, the power line 211, the active region 2P3, the dummy gate interconnects 235 to 238, and the local interconnects 244 to 246 are provided on the side facing the inverter cell CI2 in the logical unit LC. It is therefore possible to reduce variations in the finished shape of the layout pattern of cells placed inward with respect to the terminal cells in the circuit block, whereby reduction in the manufacturing variations, improvement in the yield, and improvement in the reliability, of the semiconductor integrated circuit device can be achieved.

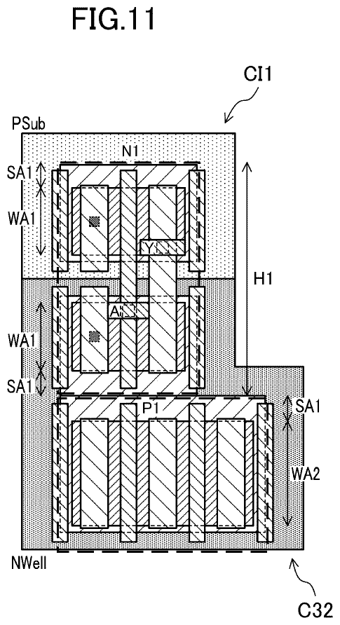

FIG. 11 is a plan view showing a layout structure of a terminal cell according to an alteration of this embodiment. In the configuration of FIG. 11, as in the configuration of FIG. 10, the lower VSS-side part of the terminal cell C32 in FIG. 9 is omitted. The terminal cell C32 in FIG. 11 is smaller in size in the Y direction than cells having the height H2 in the cell rows CR2 inside the logical unit LC. The terminal cell C32 in FIG. 11 has only a p-type transistor, having no n-type transistor.

In the configuration of FIG. 11, also, it is possible to reduce variations in the finished shape of the layout pattern of cells placed inward with respect to the terminal cells in the circuit block, whereby reduction in the manufacturing variations, improvement in the yield, and improvement in the reliability, of the semiconductor integrated circuit device can be achieved.

Note that, while the configuration of the VSS-side part is entirely omitted in the configurations of FIGS. 10 and 11, the VSS-side part may be partly omitted. Also, when the VSS-side part of the terminal cell is located adjacent to a cell constituting the logical unit LC, the VDD-side part may be omitted. In this case, the terminal cell will have only an n-type transistor, having no p-type transistor.

While the circuit block is rectangular in FIG. 1, the shape is not limited to this. Also, while six cell rows are arranged in the circuit block in FIG. 1, the number of cell rows arranged in the circuit block is not limited to this.

While the nanosheets have the structure of three sheets lying one above another and the cross-sectional shape of the sheet structure is illustrated as a rectangle in the above embodiments, the number of nanosheets, and the cross-sectional shape, of the sheet structure are not limited to these.

While nanosheet FETs are used as the transistors in the above embodiments, the type of the transistors is not limited to this. For example, fin FETs or other types of transistors may be used.

According to the present disclosure, in a semiconductor integrated circuit device having standard cells different in height, reduction in manufacturing variations, improvement in yield, and improvement in reliability can be achieved. It is therefore possible to achieve downsizing, and improvement in the performance, of the semiconductor integrated circuit device, for example.

1. A semiconductor integrated circuit device, comprising:
a first cell row including a plurality of standard cells arranged in a first direction; and
a second cell row including a plurality of standard cells arranged in the first direction,
wherein
the first cell row includes
a first standard cell including a first nanosheet extending in the first direction, the first standard cell having a logical function, and
a second standard cell adjacent to the first standard cell, including a second nanosheet extending in the first direction, the second standard cell having no logical function,
the first nanosheet and the second nanosheet are the same in width and position in a second direction perpendicular to the first direction,
the second cell row includes
a third standard cell including a third nanosheet extending in the first direction, the third standard cell having a logical function, and
a fourth standard cell adjacent to the third standard cell, including a fourth nanosheet extending in the first direction, the fourth standard cell having no logical function,
the third nanosheet and the fourth nanosheet are the same in width and position in the second direction,
the first cell row includes
a first power line formed on a back side of a transistor of the first standard cell, extending in the first direction, having overlaps with the first and second nanosheets in planar view, and supplying a first power supply voltage,
the second cell row includes
a second power line formed in a same interconnect layer as the first power line, extending in the first direction, having overlaps with the third and fourth nanosheets in planar view, and supplying the first power supply voltage, and
the third and fourth nanosheets are greater in width in the second direction than the first and second nanosheets.

2. The semiconductor integrated circuit device of claim 1, wherein
the second power line is greater in width in the second direction than the first power line.

3. The semiconductor integrated circuit device of claim 1, wherein
at least one of the second and fourth standard cells is a terminal cell.

4. The semiconductor integrated circuit device of claim 1, wherein
at least one of the second and fourth standard cells is a filler cell.

5. The semiconductor integrated circuit device of claim 1, wherein
the first and second power lines are formed in an interconnect layer provided in a first semiconductor chip in which the first, second, third, and fourth nanosheets are formed.

6. The semiconductor integrated circuit device of claim 1, wherein
the first and second power lines are formed in an interconnect layer provided in a second semiconductor chip bonded to a back of a first semiconductor chip in which the first, second, third, and fourth nanosheets are formed.

7. A semiconductor integrated circuit device, comprising
a plurality of cell rows each including a plurality of standard cells arranged in a first direction,
wherein
the plurality of cell rows include
a first cell row including a first standard cell having a first nanosheet extending in the first direction, the first standard cell having a logical function,
a second cell row adjacent to the first cell row in a second direction perpendicular to the first direction, having a height different from a height of the first cell row, and including a second standard cell having a second nanosheet extending in the first direction, and
a third cell row located on an end of the plurality of cell rows in the second direction, adjoining the first cell row on the side opposite to the second cell row, and including a third standard cell having a third nanosheet extending in the first direction, the third standard cell having no logical function,
the first cell row includes
a first power line formed on a back side of a transistor of the first standard cell, extending in the first direction, having an overlap with the first nanosheet in planar view, and supplying a first power supply voltage,
the second cell row includes
a second power line formed in a same interconnect layer as the first power line, extending in the first direction, having an overlap with the second nanosheet in planar view, and supplying the first power supply voltage, and
the third cell row includes
a third power line formed in a same interconnect layer as the first and second power lines, extending in the first direction, having an overlap with the third nanosheet in planar view, and supplying the first power supply voltage,
the first nanosheet and the second nanosheet are different in width in the second direction, and
the third nanosheet and the second nanosheet are the same in width in the second direction.

8. The semiconductor integrated circuit device of claim 7, wherein
the second power line is different in width in the second direction from the first power line.

9. The semiconductor integrated circuit device of claim 7, wherein
the third standard cell is smaller in size in the second direction than the second standard cell.

10. The semiconductor integrated circuit device of claim 7, wherein
the third standard cell includes only either one of a p-type transistor and an n-type transistor.

11. The semiconductor integrated circuit device of claim 7, wherein
the first, second, and third power lines are formed in an interconnect layer provided in a first semiconductor chip in which the first, second, and third nanosheets are formed.

12. The semiconductor integrated circuit device of claim 7, wherein
the first, second, and third power lines are formed in an interconnect layer provided in a second semiconductor chip bonded to a back of a first semiconductor chip in which the first, second, and third nanosheets are formed.
